(19) United States
(12) Patent Application Publication
(10) Pub. No.: US 2007/0221984 A1
(43) Pub. Date: Sep. 27, 2007

(54) NONVOLATILE SEMICONDUCTOR MEMORY DEVICE AND METHOD FOR MANUFACTURING SAME

(75) Inventor: Shigeru Kinoshita, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/685,889

(22) Filed: Mar. 14, 2007

(30) Foreign Application Priority Data
Mar. 27, 2006 (JP) 2006-086381

(51) Int. Cl. H01L 29/788

(52) U.S. Cl. 257/315

(57) ABSTRACT

A nonvolatile semiconductor memory device includes: a semiconductor layer; a gate insulating film provided on the semiconductor layer; a floating gate electrode provided on the gate insulating film; a control gate electrode opposed to an upper face of the floating gate electrode; a first dielectric film interposed between the upper face of the floating gate electrode and the control gate electrode; and a second dielectric film. The second dielectric film is provided adjacent to a side face of the floating gate electrode and has a lower relative dielectric constant than the first dielectric film.

### CROSS-REFERENCE TO RELATED APPLICATIONS

This application is based upon and claims the benefit of priority from the prior Japanese Patent Application No. 2006-086381, filed on Mar. 27, 2006; the entire contents of which are incorporated herein by reference.

### BACKGROUND OF THE INVENTION

1. Field of the Invention

This invention relates to a nonvolatile semiconductor memory device and a method for manufacturing the same, and more particularly to a nonvolatile semiconductor memory device and a method for manufacturing the same where a transistor having a double gate structure composed of a control gate electrode and a floating gate electrode is used as a memory cell.

2. Background Art

In recent years, nonvolatile semiconductor memory devices, which allow electrical bulk delete and rewrite of data and in which the written data can be retained without power supply, are widely used particularly in mobile devices. A nonvolatile semiconductor memory device is composed of a memory MOS (Metal Oxide Semiconductor) transistor, which has a tiny floating gate electrode surrounded by an insulating film, and interconnects for data input/output. The memory device retains memory by accumulating electric charge in the floating gate electrode. From the viewpoint of ensuring sufficient capacitive coupling between the floating gate electrode and the control gate electrode, an ONO film (a laminated film having a silicon nitride film sandwiched between two silicon oxide films), which has a higher relative dielectric constant than a silicon oxide film, is often interposed between the floating gate electrode and the control gate electrode (see e.g. JP 2004-214510A).

The ONO film is interposed also between adjacent floating gate electrodes. Thus, when the distance between adjacent floating gate electrodes decreases with the progress of device downscaling, the capacitance between floating gate electrodes increases, also partly because an ONO film having a relatively high relative dielectric constant is interposed between the floating gate electrodes. The increased capacitance between floating gate electrodes may lead to deteriorated electrical characteristics such as variation of threshold voltage.

### SUMMARY OF THE INVENTION

According to an aspect of the invention, there is provided a nonvolatile semiconductor memory device including: a semiconductor layer; a gate insulating film provided on the semiconductor layer; a floating gate electrode provided on the gate insulating film; a control gate electrode opposed to an upper face of the floating gate electrode; a first dielectric film interposed between the upper face of the floating gate electrode and the control gate electrode; and a second dielectric film provided adjacent to a side face of the floating gate electrode and having a lower relative dielectric constant than the first dielectric film.

According to another aspect of the invention, there is provided a method for manufacturing a nonvolatile semiconductor memory device, including: sequentially forming a gate insulating film, a floating gate electrode, a first dielectric film, and a first conductor layer on a semiconductor layer, and forming a trench in the semiconductor layer, the gate insulating film, the floating gate electrode, the first dielectric film, and the first conductor layer; providing a device isolation insulating layer on a portion inside the trench, the portion being opposed at least to the semiconductor layer and the gate insulating film; forming a second dielectric film on the device isolation insulating layer so as to cover the floating gate electrode protruding from the device isolation insulating layer, the first dielectric film, and the first conductor layer, the second dielectric film having a lower relative dielectric constant than the first dielectric film; removing at least a portion of the second dielectric film on the first conductor layer; and forming a second conductor layer opposed to an upper face of the floating gate electrode across the first dielectric film, the second conductor layer being in contact with the first conductor layer exposed by the removal of the second dielectric film.

According to another aspect of the invention, there is provided a method for manufacturing a nonvolatile semiconductor memory device, including: sequentially forming a gate insulating film, a floating gate electrode, and a first dielectric film on a semiconductor layer, and forming a trench in the semiconductor layer, the gate insulating film, the floating gate electrode, and the first dielectric film; providing a device isolation insulating layer on a portion inside the trench, the portion being opposed at least to the semiconductor layer and the gate insulating film; forming a second dielectric film on the device isolation insulating layer so as to cover the floating gate electrode protruding from the device isolation insulating layer and the first dielectric film, the second dielectric film having a lower relative dielectric constant than the first dielectric film; removing the second dielectric film on the first dielectric film; and forming a control gate electrode opposed to an upper face of the floating gate electrode across the first dielectric film, the first dielectric film having an upper face from which the second dielectric film has been removed.

### BRIEF DESCRIPTION OF THE DRAWINGS

FIG. 1 is a schematic view illustrating the cross-sectional structure of the main part of a nonvolatile semiconductor memory device according to a first embodiment of the invention.

FIG. 2 is a perspective view schematically showing the main part of a nonvolatile semiconductor memory device according to a comparative example.

FIG. 3 is a plan view schematically showing the positional relationship between a control gate electrode (word line) and a semiconductor layer (active region) in the nonvolatile semiconductor memory device shown in FIG. 2.

FIG. 4 shows the A-A cross section in FIG. 2.

FIG. 5 shows the B-B cross section in FIG. 2.

FIG. 6 is a graph illustrating the relationship of the inter-device distance to the capacitance between floating gate electrodes.

FIG. 7 is a schematic view for illustrating the capacitive coupling between floating gate electrodes.

FIG. 8 is a threshold voltage distribution diagram where quaternary logical data (“01”, “00”, “10”, and “11”) is stored in one memory cell.

FIGS. 9 to 13 are process cross-sectional views illustrating the main part of a process of manufacturing a nonvolatile semiconductor memory device according to the first embodiment of the invention.

FIG. 14 is a schematic view illustrating the cross-sectional structure of the main part of a nonvolatile semiconductor memory device according to a second embodiment of the invention.

FIG. 15 is a process cross-sectional view illustrating the main part of a process of manufacturing a nonvolatile semiconductor memory device according to the second embodiment.

FIG. 16 is a schematic view illustrating the cross-sectional structure of the main part of a nonvolatile semiconductor memory device according to a third embodiment of the invention.

FIG. 17 is a schematic view illustrating the cross-sectional structure of the main part of a nonvolatile semiconductor memory device according to a fourth embodiment of the invention.

FIG. 18 is a schematic view illustrating the cross-sectional structure of the main part of a nonvolatile semiconductor memory device according to a fifth embodiment of the invention.

### DETAILED DESCRIPTION OF THE INVENTION

### First Embodiment

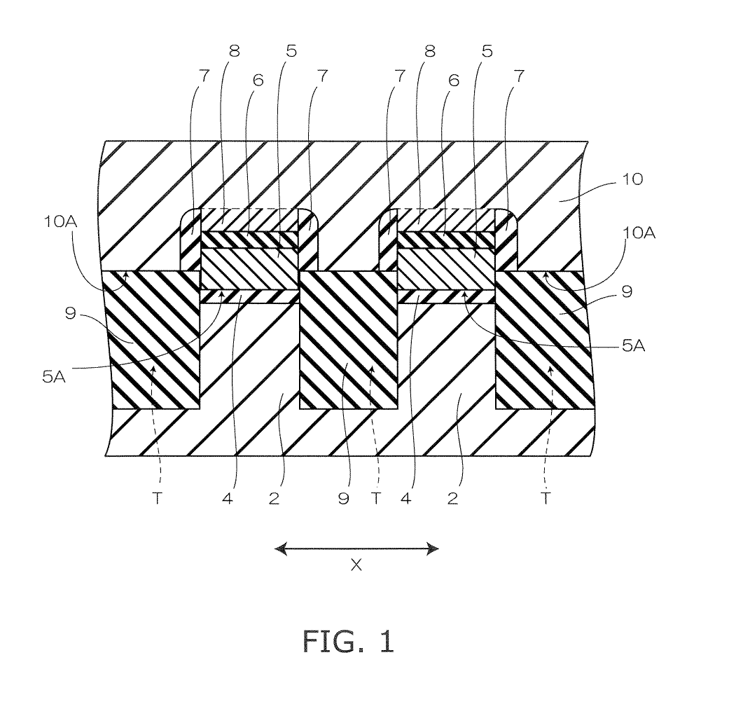

FIG. 1 is a schematic cross-sectional view illustrating the cross-sectional structure of the main part of a nonvolatile semiconductor memory device according to a first embodiment of the invention.

In this embodiment, by forming trenches T in a silicon substrate, a plurality of semiconductor layers 2 spaced from each other and arranged in a first direction x are formed. Each semiconductor layer 2 extends in a second direction y (the direction through the page in FIG. 1) substantially orthogonal to the first direction x. In the surface portion of the semiconductor layer 2, a source region and a drain region are formed, which are spaced in the second direction.

A gate insulating film (tunnel insulating film) 4 is provided on the semiconductor layer 2. A floating gate electrode 5 is provided on the gate insulating film 4. The floating gate electrode 5 is illustratively made of polycrystalline silicon. The trench T is filled inside with a device isolation insulating layer 9 having a STI (Shallow Trench Isolation) structure. The upper face position of the device isolation insulating layer 9 reaches a halfway point of the floating gate electrode 5. The device isolation insulating layer 9 is interposed between the semiconductor layers 2 and between the gate insulating films 4 that are adjacent to each other as viewed in the first direction x. The gate insulating film 4 and the device isolation insulating layer 9 are illustratively made of silicon oxide.

A first dielectric film 6 is provided on the floating gate electrode 5. The first dielectric film 6 is made of a dielectric having a relative dielectric constant of 5 or more, which can illustratively be any one of Al₂O₃, HfAlOₓ, HfSiOₓ, ZnOₓ, Ta₂O₅, SrO, Si₃N₄, MgO, Y₂O₃, HfO₂, ZrO₂, and Bi₂O₃, or a composite film formed by laminating two or more thereof. Furthermore, the first dielectric film 6 can alternatively be a composite film formed from at least one of these materials and a silicon oxide film. The first dielectric film 6 is provided only on the upper face of the floating gate electrode 5, and not provided on (not in contact with) the side face of the floating gate electrode 5. That is, the first dielectric film 6 is a flat film without steps. On the first dielectric film 6 is provided a polycrystalline silicon layer 8, which constitutes part of a control gate electrode 10.

A second dielectric film 7 is provided adjacently on the upper portion of the side face of the floating gate electrode 5 that is not covered with the device isolation insulating layer 9, on the side face of the first dielectric film 6, and on the side face of the polycrystalline silicon layer 8. The second dielectric film 7 is illustratively made of silicon oxide, which has a lower relative dielectric constant than the first dielectric film 6.

A control gate electrode 10 illustratively made of polycrystalline silicon is provided on the device isolation insulating layer 9 so as to cover the polycrystalline silicon layer 8 and the second dielectric film 7. The control gate electrode 10 is joined with the polycrystalline silicon layer 8, which also functions as part of the control gate electrode 10.

A plurality of control gate electrodes 10 are juxtaposed in the second direction (the direction through the page in FIG. 1), and each control gate electrode 10 extends in the first direction x. The device isolation insulating layer 9 is interposed between the lower portions of the side faces of the floating gate electrodes 5 that are adjacent to each other as viewed in the first direction x. A structure having a control gate electrode 10 sandwiched between the second dielectric films 7 is interposed between the upper portions of the side faces of the floating gate electrodes 5 that are adjacent to each other as viewed in the first direction x.

The floating gate electrode 5 is located at an intersection of the control gate electrode 10 and the semiconductor layer 2 which are arranged in a matrix configuration. The floating gate electrode 5 is surrounded by the device isolation insulating layer 9, the gate insulating film 4, the first dielectric film 6, and the second dielectric film 7, and is not electrically connected to anywhere. Hence, even if the power is turned off after electrons are electrically injected into or ejected from the floating gate electrode 5, no electrons in the floating gate electrode 5 leak out of the floating gate electrode 5, or no electrons newly enter the floating gate electrode 5. That is, nonvolatility is achieved.

In the following, the nonvolatile semiconductor memory device of this embodiment is described in more detail with reference to a comparative example.

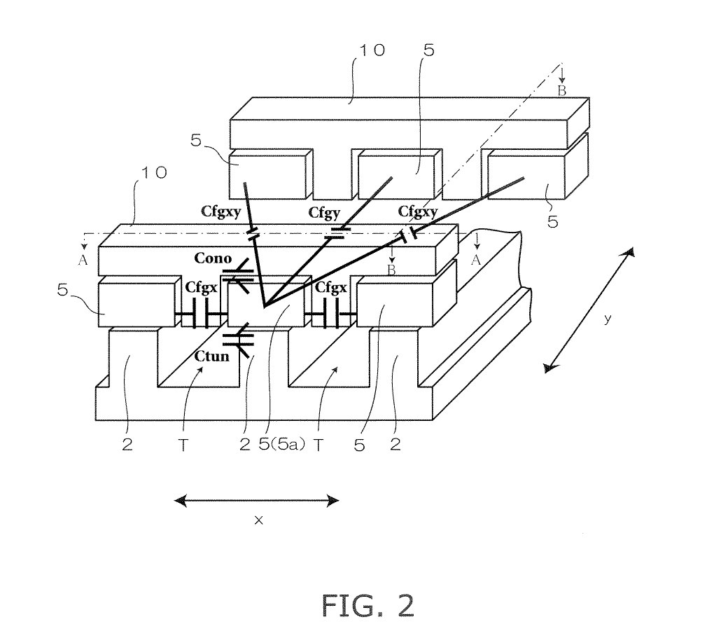

FIG. 2 is a perspective view schematically showing the main part of a nonvolatile semiconductor memory device according to a comparative example, which was investigated by the inventor in the course of reaching the invention. Here, the cross section shown in FIG. 1 corresponds to the A-A cross section in FIG. 2, that is, the cross section cut along the extending direction (the first direction x) of the control gate electrode (word line) 10.

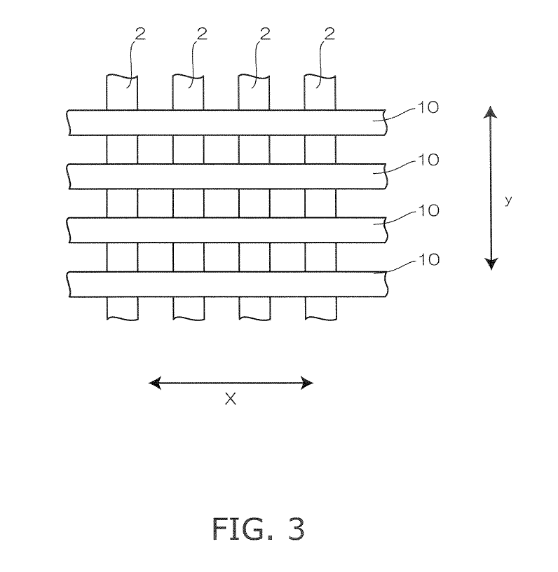

FIG. 3 is a plan view schematically showing the positional relationship between a control gate electrode (word line) 10 and a semiconductor layer (active region) 2 in the nonvolatile semiconductor memory device shown in FIG. 2.

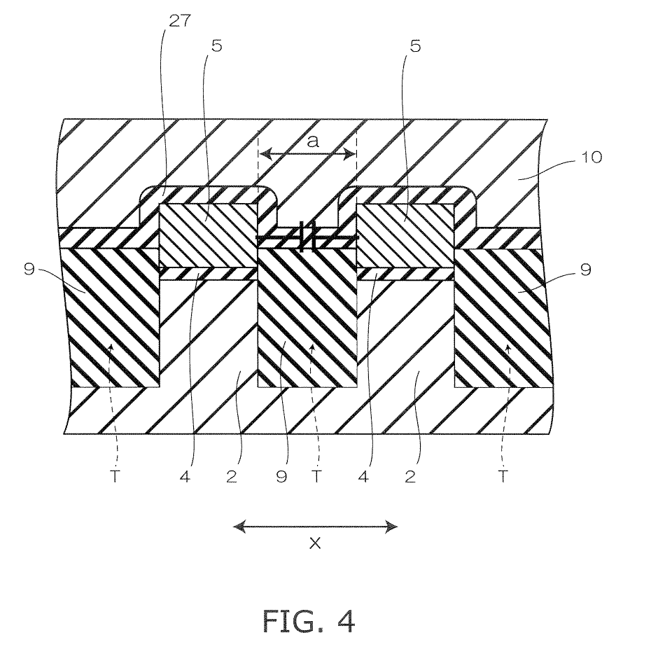

FIG. 4 shows the A-A cross section in FIG. 2.

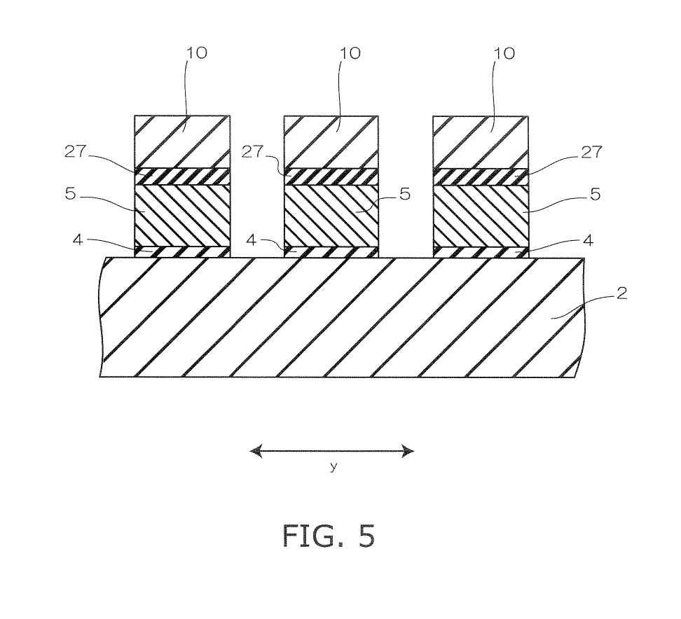

FIG. 5 shows the B-B cross section in FIG. 2.

In this comparative example again, by forming trenches T in a silicon substrate, a plurality of semiconductor layers 2 spaced from each other and arranged in a first direction x are formed. Each semiconductor layer 2 extends in a second direction y substantially orthogonal to the first direction x. The trench T is filled with a device isolation insulating layer 9.

A floating gate electrode 5 is provided above the semiconductor layer 2 via the gate insulating film (tunnel insulating film) 4. Through the intermediary of a dielectric film 27, a control gate electrode 10 is provided above the floating gate electrode 5 and between the floating gate electrodes 5 that are adjacent to each other as viewed in the first direction x.

A plurality of control gate electrodes 10 are juxtaposed in the second direction y, and each control gate electrode 10 extends in the first direction x. The floating gate electrode 5 is located at an intersection of the control gate electrode 10 and the semiconductor layer 2. The floating gate electrode 5 is surrounded by the gate insulating film 4, the device isolation insulating layer 9, and the dielectric film 27, and is not electrically connected to anywhere.

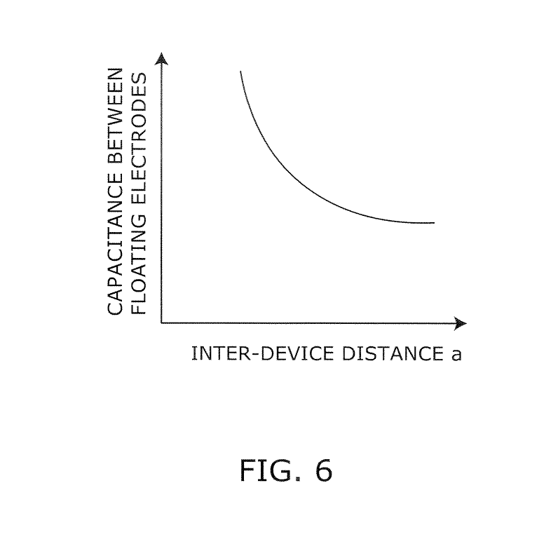

In a nonvolatile semiconductor memory device thus configured, when the distance a (see FIG. 4) between adjacent floating gate electrodes 5 decreases with the progress of device downscaling, the capacitance between floating gate electrodes increases as shown in the graph of FIG. 6.

In FIG. 6, the horizontal axis represents the inter-device distance, and the vertical axis represents the capacitance between floating gate electrodes (2Cfgx+2Cfgy+4Cfgxy). Cfgx denotes the capacitance between floating gate electrodes that are adjacent to each other in the first direction x. Cfgy denotes the capacitance between floating gate electrodes that are adjacent to each other in the second direction y. Cfgxy denotes the capacitance between floating gate electrodes that are adjacent to each other in the diagonal direction.

Increased capacitance between floating gate electrodes contributes to deteriorated electrical characteristics of the nonvolatile semiconductor memory device (e.g. variation of threshold voltage Vth).

The variation ΔVth of threshold voltage Vth is given by:
ΔVth={(ΔV1+ΔV2)Cfgx+ΔV4Cfgy+(ΔV3+ΔV5)Cfgxy}/(Ctun+Cono+2Cfgx+2Cfgy+4Cfgxy) (1)

Here, ΔV1 to ΔV5 denote the variation of threshold voltage Vth in the adjacent cells, where the variation occur when a write operation on a floating gate electrode 5a shown in FIG. 2 is completed and then a write operation on floating gate electrodes being adjacent in respective directions is performed. The cell corresponding to the floating gate electrode 5a undergoes Vth variation in response to the variation of the write state (Vth) in the adjacent cells.

Ctun denotes the capacitance between the semiconductor layer and the floating gate electrode. Cono denotes the capacitance between the floating gate electrode and the control gate electrode.

It is seen from equation (1) that, when the capacitance between floating gate electrodes (2Cfgx+2Cfgy+4Cfgxy) varies, the threshold voltage Vth also varies.

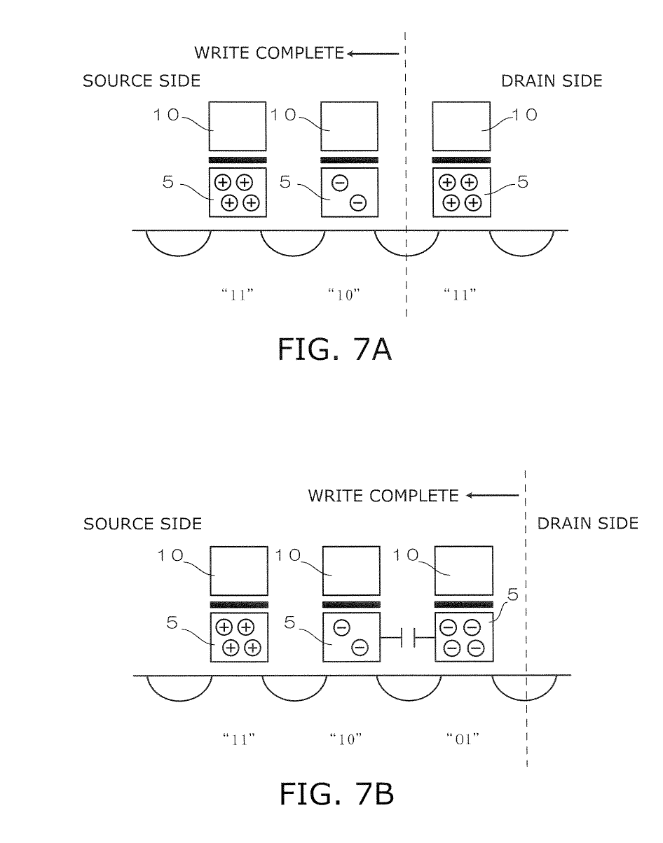

FIG. 7 is a schematic view for illustrating the capacitive coupling between floating gate electrodes.

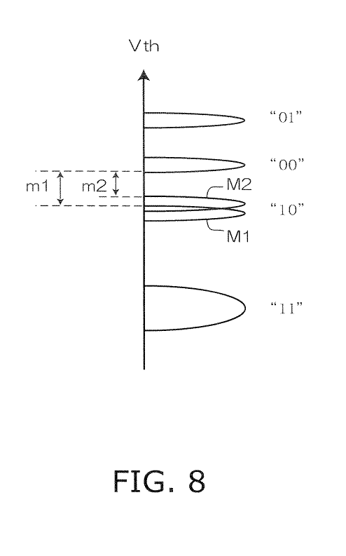

FIG. 8 is a threshold voltage distribution diagram where quaternary logical data (“01”, “00”, “10”, and “11”) is stored in one memory cell.

In a nonvolatile semiconductor memory device, electrons are injected from the semiconductor layer 2 into the floating gate electrode 5 by the quantum-mechanical tunneling phenomenon, and thereby the electrons are accumulated in the floating gate electrode 5. The threshold voltage Vth of the memory cell transistor is shifted depending on the amount of electrons accumulated in the floating gate electrode 5, whereby a logical data is stored.

In the case of a write operation from the state of FIG. 7A to the state of FIG. 7B, when the capacitance between adjacent floating gate electrodes 5 is large, the potential of the floating gate electrode 5 retaining data “10”, for example, may be affected by the electric charge in the adjacent floating gate electrode 5. Hence the threshold voltage distribution M1 representing data “10” is shifted to a threshold voltage distribution M2, and the spacing to the threshold voltage distribution representing data “00” is narrowed from m1 to m2. This may contribute to reducing device reliability.

Furthermore, reduction of write voltage requires increasing the capacitive coupling ratio between the control gate electrode 10 and the floating gate electrode 5. The coupling ratio is given by Cono/(Ctun+Cono+2Cfgx+2Cfgy+4Cfgxy). Hence, increase of the capacitance between floating gate electrodes (2Cfgx+2Cfgy+4Cfgxy) makes it difficult to ensure a high coupling ratio between the control gate electrode 10 and the floating gate electrode 5.

From the viewpoint of ensuring a high coupling ratio between the control gate electrode 10 and the floating gate electrode 5, a film having a relatively high relative dielectric constant such as an ONO film has been used for the dielectric film between the floating gate electrode 5 and the control gate electrode 10. In the structure of the comparative example shown in FIG. 4, the ONO film 27 is formed also on the device isolation insulating layer 9 between adjacent floating gate electrodes 5, and hence contributes to increasing the capacitance between floating gate electrodes.

Furthermore, a film having a higher relative dielectric constant such as a film containing aluminum (Al) or hafnium (Hf) may be used as the dielectric film 27. However, when the control gate electrode (word line) 10 is divided into a plurality of lines by e.g. RIE (Reactive Ion Etching) as shown in FIG. 5, the dielectric film 27 is difficult to remove. In particular, when the dielectric film 27 is formed to cover steps as shown in FIG. 4, the processing is more difficult.

In contrast, in the nonvolatile semiconductor memory device according to this embodiment illustrated in FIG. 1, a first dielectric film 6 having a relatively high relative dielectric constant is provided directly on the floating gate electrode 5 to ensure a sufficient capacitance between the floating gate electrode 5 and the control gate electrode 10, whereas a second dielectric film 7 and a device isolation insulating layer 9 having a lower relative dielectric constant than the first dielectric film 6 are provided on the side face of the floating gate electrode 5. Thus the capacitance between adjacent floating gate electrodes 5 can be reduced.

Furthermore, part of the control gate electrode 10 is interposed between adjacent floating gate electrodes 5 on the device isolation insulating layer 9. The shielding effect of this control gate electrode 10 can decrease interferences due to the capacitive coupling between floating gate electrodes 5. Moreover, the capacitive coupling ratio between the control gate electrode 10 and the floating gate electrode 5 can be increased by decreasing the capacitance between floating gate electrodes 5, and the write voltage can also be reduced.

Thus, according to this embodiment, the capacitive coupling ratio between the floating gate electrode 5 and the control gate electrode 10 can be increased to reduce the write voltage, while reducing the deterioration of electrical characteristics such as threshold voltage variation due to the capacitance between floating gate electrodes 5.

In the example shown in FIG. 1, the control gate electrode 10 is opposed to both side faces of the floating gate electrode 5 via the second dielectric film 7. The lower end 10A of this opposed portion of the control gate electrode 10 is located above the lower end 5A of the floating gate electrode 5. By this configuration, the control gate electrode 10 can be distanced from the semiconductor layer 2. As a result, the leakage between the control gate electrode 10 and the semiconductor layer 2 can be reduced.

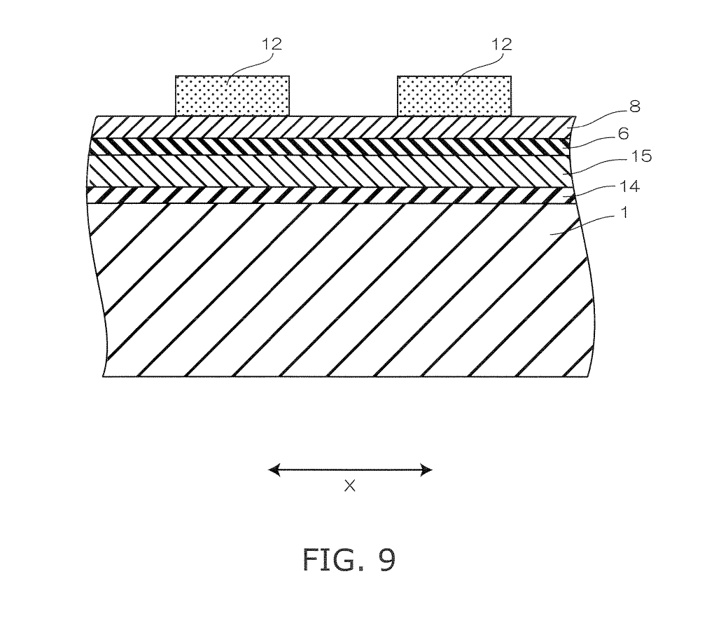

Next, an example method for manufacturing a nonvolatile semiconductor memory device according to this embodiment is described. FIGS. 9 to 13 are process cross-sectional views illustrating the main part of a process of manufacturing a nonvolatile semiconductor memory device according to this embodiment.

First, as shown in FIG. 9, a silicon oxide film 14, a polycrystalline silicon layer 15, a first dielectric film 6, and a polycrystalline silicon layer 8 are sequentially formed on a silicon substrate 1. Then a patterned etching mask 12 is formed on the polycrystalline silicon layer 8.

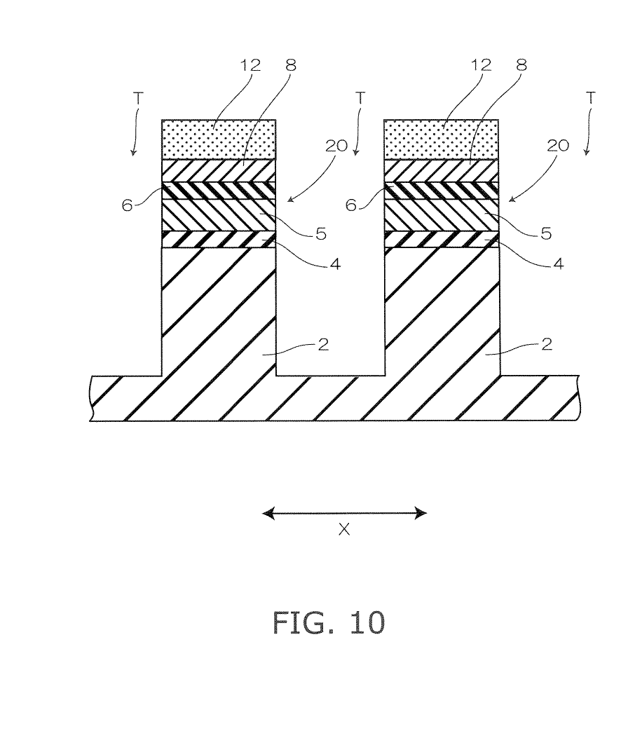

The etching mask 12 is used as a mask to etch the polycrystalline silicon layer 8, the first dielectric film 6, the polycrystalline silicon layer 15, the silicon oxide film 14, and the silicon substrate 1 by RIE (Reactive Ion Etching). As shown in FIG. 10, this results in a plurality of structures 20 spaced from each other by trenches T. Each structure 20 has a semiconductor layer 2 made of silicon, a gate insulating film 4 made of silicon oxide, a floating gate electrode 5 made of polycrystalline silicon, a first dielectric film 6 made of a dielectric having a higher relative dielectric constant than silicon oxide, and a polycrystalline silicon layer 8, which are sequentially laminated from bottom.

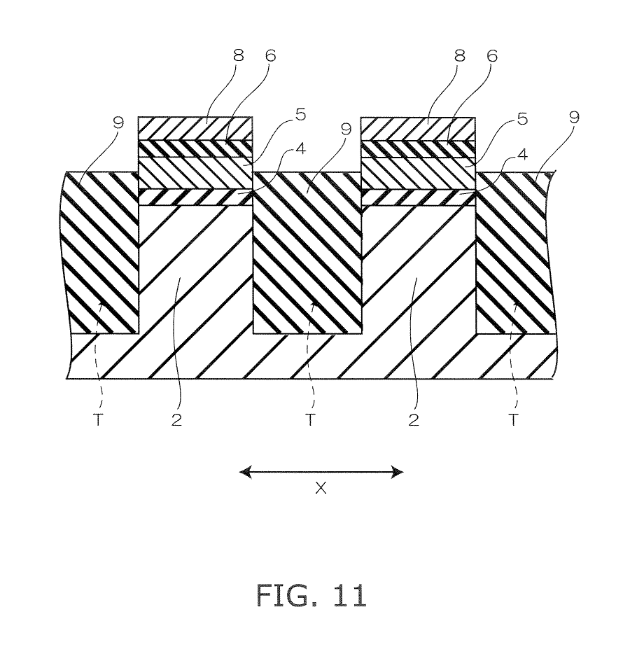

Next, by heating in an oxygen gas atmosphere, a silicon oxide film of several nanometers (not shown) is formed on the inner wall of the trench T. Then, by e.g. HDPCVD (High Density Plasma Chemical Vapor Deposition), a device isolation insulating layer 9 made of silicon oxide is deposited on the entire surface to bury the inside of the trench T. Then the device isolation insulating layer 9 is planarized by CMP (Chemical Mechanical Polishing) and heated in a nitrogen atmosphere. Then the etching mask 12 on the polycrystalline silicon layer 8 is removed, and the device isolation insulating layer 9 is etched back halfway through the floating gate electrode 5 by RIE as shown in FIG. 11.

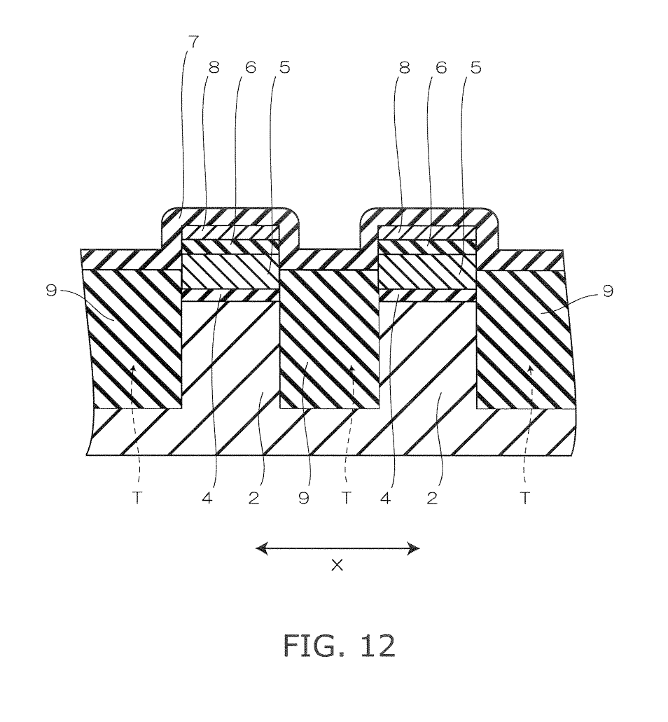

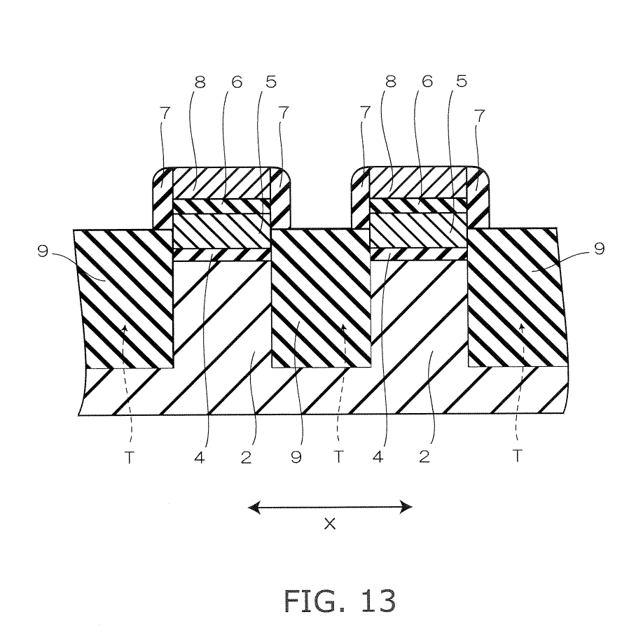

Then, as shown in FIG. 12, a second dielectric film 7 is deposited on the device isolation insulating layer 9 so as to cover part of the floating gate electrode 5 protruding upward from the device isolation insulating layer 9, the first dielectric film 6, and the polycrystalline silicon layer 8. Then, as shown in FIG. 13, the second dielectric film 7 on the polycrystalline silicon layer 8 and on the device isolation insulating layer 9 is etched by RIE to leave the second dielectric film 7 only on the side face of part (upper portion) of the floating gate electrode 5 protruding upward from the device isolation insulating layer 9, the side face of the first dielectric film 6, and the side face of the polycrystalline silicon layer 8. Then a control gate electrode 10 made of polycrystalline silicon is deposited by reduced pressure CVD. Thus the structure shown in FIG. 1 is obtained.

In this embodiment, as described above with reference to FIGS. 9 and 10, a silicon oxide film 14 serving as a gate insulating film 4, a polycrystalline silicon layer 15 serving as a floating gate electrode 5, and a first dielectric film 6 are laminated on a silicon substrate 1 serving as a semiconductor layer 2. Then trenches T for device isolation are formed by RIE. That is, a first dielectric film 6, which is flat without steps on the floating gate electrode 5, is obtained in conjunction with the process of separating the semiconductor layer 2, the gate insulating film 4, and the floating gate electrode 5 in the first direction x (the extending direction of the control gate electrode 10 or word line). Hence, even if a dielectric having a high relative dielectric constant but being less workable such as a dielectric containing aluminum (Al) or hafnium (Hf) is used for the first dielectric film 6, the first dielectric film 6 is easier to process than the dielectric film 27 covering steps as shown in FIG. 4 when the control gate electrode (word line) 10 is processed for division into a plurality of lines, because the first dielectric film 6 is formed as a flat film without steps. As a result, the manufacturing cost can be reduced.

Furthermore, by etching back using RIE from the state of FIG. 12, the second dielectric film 7 is left on the side faces of the floating gate electrode 5 protruding upward from the device isolation insulating layer 9, the first dielectric film 6, and the polycrystalline silicon layer 8, whereas the second dielectric film 7 on the polycrystalline silicon layer 8 is removed. Thus the effort, time, and cost required for processing can be reduced relative to the case of using photolithography.

In the following, other embodiments of the invention are described. The same components as those described earlier are marked with the same reference numerals and not described in detail.

### Second Embodiment

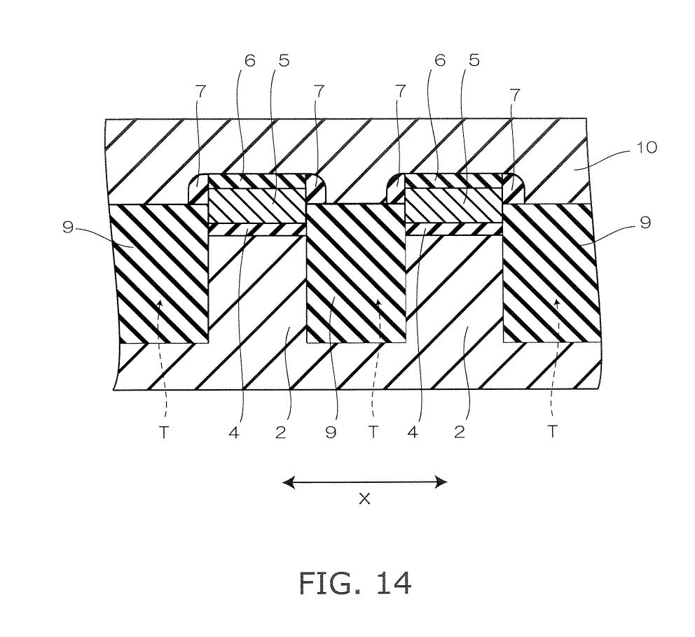

FIG. 14 is a schematic view illustrating the cross-sectional structure of the main part of a nonvolatile semiconductor memory device according to a second embodiment of the invention.

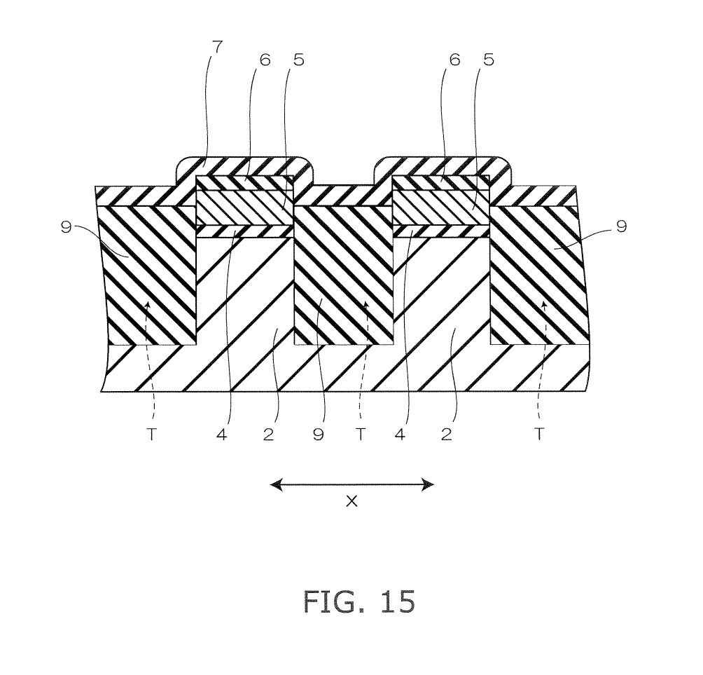

In this embodiment, no polycrystalline silicon layer 8 is provided on the first dielectric film 6. More specifically, without forming a polycrystalline silicon layer 8 on the first dielectric film 6 in FIG. 9, a process as shown in FIGS. 9 to 11 is conducted. Then, as shown in FIG. 15, a second dielectric film 7 is deposited on the device isolation insulating layer 9 so as to cover part of the floating gate electrode 5 protruding upward from the device isolation insulating layer 9 and the first dielectric film 6. Then the second dielectric film 7 on the first dielectric film 6 and on the device isolation insulating layer 9 is etched by RIE to leave the second dielectric film 7 only on the side face of part of the floating gate electrode 5 protruding upward from the device isolation insulating layer 9 and on the side face of the first dielectric film 6. Then a control gate electrode 10 made of polycrystalline silicon is deposited by reduced pressure CVD. Thus the structure shown in FIG. 14 is obtained.

In this embodiment again, a first dielectric film 6 having a relatively high relative dielectric constant is provided directly on the floating gate electrode 5 to ensure a sufficient capacitance between the floating gate electrode 5 and the control gate electrode 10, whereas a second dielectric film 7 and a device isolation insulating layer 9 having a lower relative dielectric constant than the first dielectric film 6 are provided on the side face of the floating gate electrode 5. Thus the capacitance between adjacent floating gate electrodes 5 can be reduced.

### Third Embodiment

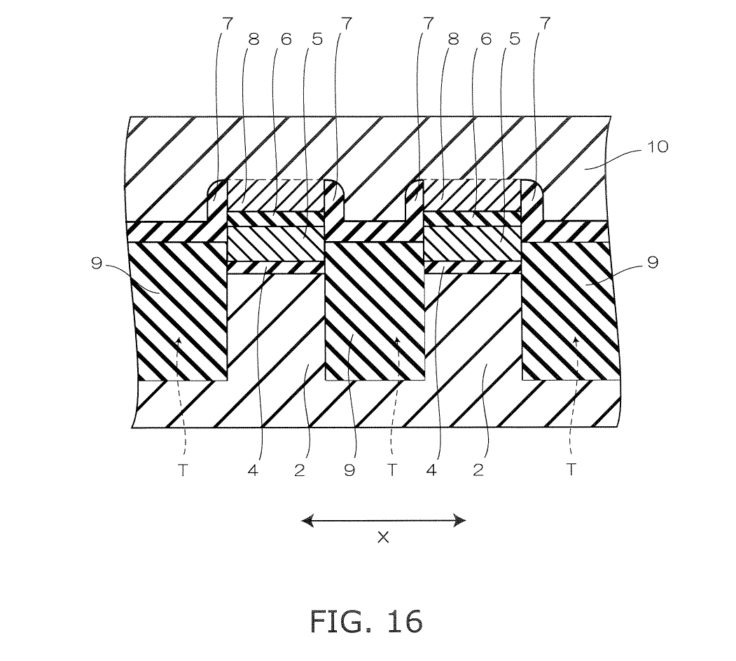

FIG. 16 is a schematic view illustrating the cross-sectional structure of the main part of a nonvolatile semiconductor memory device according to a third embodiment of the invention.

In this embodiment, the second dielectric film 7 on the polycrystalline silicon layer 8 is removed by CMP. Thus the second dielectric film 7 is left on the entire surface of the device isolation insulating layer 9.

### Fourth Embodiment

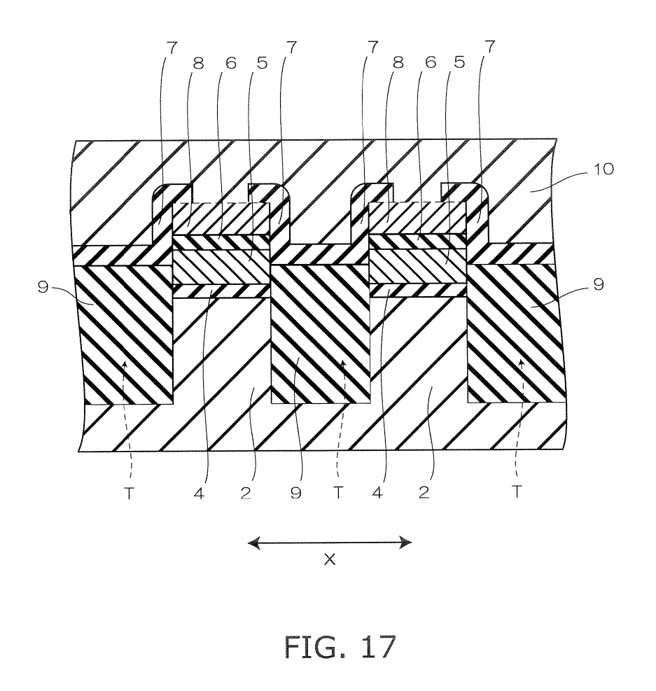

FIG. 17 is a schematic view illustrating the cross-sectional structure of the main part of a nonvolatile semiconductor memory device according to a fourth embodiment of the invention.

In this embodiment, the second dielectric film 7 on the polycrystalline silicon layer 8 is removed by photolithography. Thus the second dielectric film 7 is left on the entire surface of the device isolation insulating layer 9.

### Fifth Embodiment

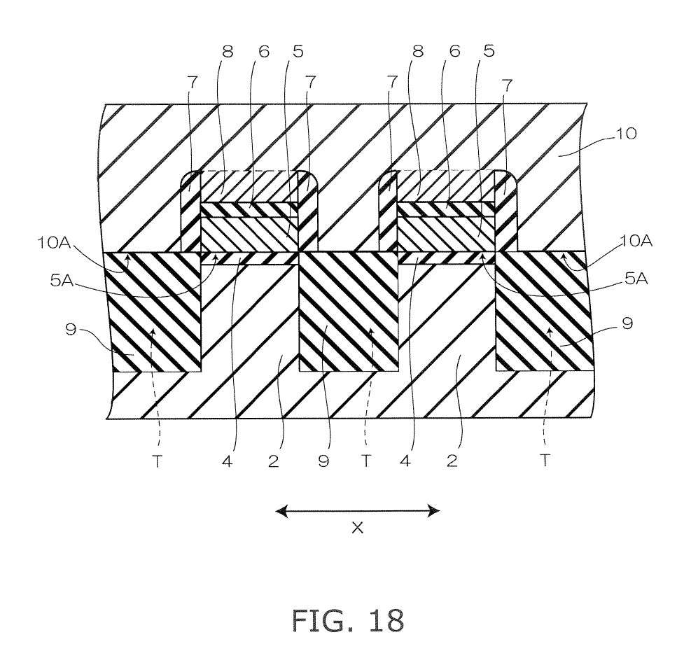

FIG. 18 is a schematic view illustrating the cross-sectional structure of the main part of a nonvolatile semiconductor memory device according to a fifth embodiment of the invention.

In this embodiment, the device isolation insulating layer 9 does not protrude upward from the gate insulating film 4, and the second dielectric film 7 covers entirely the side face of the floating gate electrode 5. The lower end 10A of the control gate electrode 10 is located substantially as high as the lower end 5A of the floating gate electrode 5. This structure can enhance the shielding effect of the control gate electrode 10 between floating gate electrodes 5 as compared with the first embodiment. That is, the coupling capacitance between adjacent floating gate electrodes 5 can be further reduced.

Embodiments of the invention have been described with reference to examples. However, the invention is not limited to these embodiments and the examples thereof. For example, the material, film thickness, size, forming method, and positional relationship of the components can be appropriately modified by those skilled in the art, and such modifications are also encompassed within the scope of the invention as long as they include the features of the invention.

1. A nonvolatile semiconductor memory device comprising:
a semiconductor layer;
a gate insulating film provided on the semiconductor layer;
a floating gate electrode provided on the gate insulating film;
a control gate electrode opposed to an upper face of the floating gate electrode;
a first dielectric film interposed between the upper face of the floating gate electrode and the control gate electrode; and
a second dielectric film provided adjacent to a side face of the floating gate electrode and having a lower relative dielectric constant than the first dielectric film.

2. The nonvolatile semiconductor memory device according to claim 1, wherein the first dielectric film has a relative dielectric constant of 5 or more.

3. The nonvolatile semiconductor memory device according to claim 1, wherein the second dielectric film extends upward relative to the first dielectric film.

4. The nonvolatile semiconductor memory device according to claim 1, wherein the control gate electrode has an opposed portion that is opposed to the side face of the floating gate electrode via the second dielectric film, and the lower end of the opposed portion is located higher than the lower end of the floating gate electrode.

5. The nonvolatile semiconductor memory device according to claim 1, wherein the control gate electrode has an opposed portion that is opposed to the side face of the floating gate electrode via the second dielectric film, and the lower end of the opposed portion is located substantially as high as the lower end of the floating gate electrode.

6. The nonvolatile semiconductor memory device according to claim 1, wherein the control gate electrode includes a polycrystalline silicon layer provided on the first dielectric film.

7. The nonvolatile semiconductor memory device according to claim 6, wherein the second dielectric film covers a side face of the polycrystalline silicon layer.

8. The nonvolatile semiconductor memory device according to claim 6, wherein the second dielectric film extends on an upper face of the polycrystalline silicon layer.

9. The nonvolatile semiconductor memory device according to claim 6, wherein the second dielectric film covers all of the side face of the floating gate electrode.

10. The nonvolatile semiconductor memory device according to claim 6, wherein the first dielectric film includes one selected from the group consisting of Al₂O₃, HfAlOₓ, HfSiOₓ, ZnOₓ, Ta₂O₅, SrO, Si₃N₄, MgO, Y₂O₃, HfO₂, ZrO₂, and Bi₂O₃.

11. The nonvolatile semiconductor memory device according to claim 1, wherein the second dielectric film is made of a silicon dioxide.

12. The nonvolatile semiconductor memory device according to claim 1, wherein the floating gate electrode is made of a polycrystalline silicon.

13. The nonvolatile semiconductor memory device according to claim 6, wherein the first dielectric film does not cover the side face of the floating gate electrode.

14. The nonvolatile semiconductor memory device according to claim 1, further comprising a device isolation insulating layer which fills a trench formed in the semiconductor layer, wherein the device isolation insulating layer covers a side face of the gate insulating film.

15. The nonvolatile semiconductor memory device according to claim 14, wherein the device isolation insulating layer covers a part of the side face of the floating gate electrode.

16. The nonvolatile semiconductor memory device according to claim 14, wherein an upper face of the device isolation insulating layer is substantially and a lower face of the floating gate electrode are substantially in a same plane.

17. The nonvolatile semiconductor memory device according to claim 14, wherein the second dielectric film extends on a upper face of the device isolation insulating layer.

18. A method for manufacturing a nonvolatile semiconductor memory device, comprising:
sequentially forming a gate insulating film, a floating gate electrode, a first dielectric film, and a first conductor layer on a semiconductor layer, and forming a trench in the semiconductor layer, the gate insulating film, the floating gate electrode, the first dielectric film, and the first conductor layer;
providing a device isolation insulating layer on a portion inside the trench, the portion being opposed at least to the semiconductor layer and the gate insulating film;
forming a second dielectric film on the device isolation insulating layer so as to cover the floating gate electrode protruding from the device isolation insulating layer, the first dielectric film, and the first conductor layer, the second dielectric film having a lower relative dielectric constant than the first dielectric film;
removing at least a portion of the second dielectric film on the first conductor layer; and
forming a second conductor layer opposed to an upper face of the floating gate electrode across the first dielectric film, the second conductor layer being in contact with the first conductor layer exposed by the removal of the second dielectric film.

19. The method for manufacturing a nonvolatile semiconductor memory device according to claim 18, wherein the first conductor layer is exposed by removing the second dielectric film using anisotropic etching.

20. A method for manufacturing a nonvolatile semiconductor memory device, comprising:
sequentially forming a gate insulating film, a floating gate electrode, and a first dielectric film on a semiconductor layer, and forming a trench in the semiconductor layer, the gate insulating film, the floating gate electrode, and the first dielectric film;
providing a device isolation insulating layer on a portion inside the trench, the portion being opposed at least to the semiconductor layer and the gate insulating film;
forming a second dielectric film on the device isolation insulating layer so as to cover the floating gate electrode protruding from the device isolation insulating layer and the first dielectric film, the second dielectric film having a lower relative dielectric constant than the first dielectric film;
removing the second dielectric film on the first dielectric film; and
forming a control gate electrode opposed to an upper face of the floating gate electrode across the first dielectric film, the first dielectric film having an upper face from which the second dielectric film has been removed.
